(19) United States
(12) Patent Application Publication
(10) Pub. No.: US 2023/0105009 A1
(43) Pub. Date: Apr. 6, 2023

(54) REMOTE CONTROL BUTTON DETECTION

(71) Applicant: Roku, Inc., San Jose, CA (US)

(72) Inventors: William Daniel Strauss, San Jose, CA (US); Adam Walter Strauss, San Jose, CA (US); Jeffrey John Peters, Scotts Valley, CA (US)

(21) Appl. No.: 17/495,187

(22) Filed: Oct. 6, 2021

(51) Int. Cl. H01H 13/702; H01H 13/81; G06F 3/02

(52) U.S. Cl. CPC H01H 13/702; H01H 13/81; G06F 3/02

(57) ABSTRACT

Disclosed herein are system, apparatus, article of manufacture, method and/or computer program product embodiments, and/or combinations and sub-combinations thereof, for using electrical button matrix scanning techniques to detect remote control buttons pressed by users. An example embodiment operates by detecting, using an electrical matrix scanning technique, an actuated electrical switch corresponding to a remote control action for a media device. The actuated electrical switch includes a first actuated electrode coupled to a first actuated electrical line of an electrical matrix, a second actuated electrode coupled to a second actuated electrical line of the electrical matrix, and a third actuated electrode coupled to a third actuated electrical line of the electrical matrix. In response to detecting the actuated electrical switch, the example embodiment operates by triggering an execution of the remote control action corresponding to the actuated electrical switch.

### BACKGROUND

### Field

This disclosure is generally directed to button input devices, such as remote controls, keyboards, and cell phones, and more particularly to using electrical button matrix scanning techniques to detect button presses.

### Background

In today's world, on-demand availability of content—such as movies, television (TV) shows and music, to name just a few examples—is commonplace. Several commercially available media systems provide such on-demand services. These media systems are controllable using various remote control devices, such as infrared (IR) remote controls, radio frequency (RF) remote controls, Wi-Fi remote controls, and Bluetooth (BT) remote controls, to name just a few examples. However, the functionality of and demands on remote control devices have increased substantially through the years, requiring greater computing power and memory usage and increasing the complexity and cost of these devices. For example, traditional remote control devices typically detect button presses in one of two ways: with a one button per general-purpose input/output (GPIO) pin setup (e.g., dedicated GPIO signal per button); or using a two-dimensional (2D) scanning matrix setup where there are pins in an X-Y matrix, which allows for more buttons with fewer pins. However, as the number of buttons increases, the complexity and cost of the processing components of these traditional remote control devices increases substantially as well. As a result, existing multi-button remote control devices can be complex and costly, require significant computational resources, and result in substantial time for desired functions to be executed by the associated media systems.

### SUMMARY

Provided herein are system, apparatus, article of manufacture, method and/or computer program product embodiments, and/or combinations and sub-combinations thereof, for using electrical button matrix scanning techniques to detect remote control buttons pressed by users. For example, the system, apparatus, article of manufacture, method and/or computer program product embodiments disclosed herein, and/or combinations and sub-combinations thereof, can increase the number of buttons on the remote control without increasing the number of GPIO pins on the inside of the remote control, such as by converting a 2D scanning matrix into a three-dimensional (3D) scanning matrix by adding “pages”; combining simultaneous button presses and counting them as a unique event; or adding extension rows and columns to a 2D scanning matrix.

An example embodiment is directed to an apparatus that includes an electrical matrix, a memory, and at least one processor coupled to the electrical matrix and the memory. The electrical matrix includes a first plurality of electrodes disposed on a substrate and electrically coupled to a first plurality of electrical lines, a second plurality of electrodes disposed on the substrate and electrically coupled to a second plurality of electrical lines, a third plurality of electrodes disposed on the substrate and electrically coupled to a third plurality of electrical lines, and a plurality of electrical switches corresponding to a plurality of remote control actions for a media device. Each electrical switch of the plurality of electrical switches includes a respective first electrode of the first plurality of electrodes, a respective second electrode of the second plurality of electrodes, and a respective third electrode of the third plurality of electrodes. Each electrical switch of the plurality of electrical switches corresponds to a respective remote control action of the plurality of remote control actions. Each electrical switch of the plurality of electrical switches is configured to be actuated by a respective one of a plurality of buttons disposed over the plurality of electrical switches in response to the respective one of the plurality of buttons being pressed by a user. The at least one processor is configured to detect, based on an electrical matrix scanning technique, an actuated electrical switch of the plurality of electrical switches corresponding to one of the plurality of buttons being pressed by the user. Subsequently, the at least one processor is configured to trigger an execution of the remote control action corresponding to the actuated electrical switch.

Another example embodiment is directed to a remote control device that includes an electrical matrix, plurality of buttons, a memory, and at least one processor coupled to the electrical matrix and the memory. The electrical matrix includes a first plurality of electrodes disposed on a substrate and electrically coupled to a first plurality of electrical lines, a second plurality of electrodes disposed on the substrate and electrically coupled to a second plurality of electrical lines, a third plurality of electrodes disposed on the substrate and electrically coupled to a third plurality of electrical lines, and a plurality of electrical switches corresponding to a plurality of remote control actions for a media device. Each electrical switch of the plurality of electrical switches includes a respective first electrode of the first plurality of electrodes, a respective second electrode of the second plurality of electrodes, and a respective third electrode of the third plurality of electrodes. Each electrical switch of the plurality of electrical switches corresponds to a respective remote control action of the plurality of remote control actions. The plurality of buttons are disposed over the plurality of electrical switches and, in response to being pressed by a user, each button in the plurality of buttons is configured to actuate a respective electrical switch of the plurality of electrical switches. The at least one processor is configured to detect, based on an electrical matrix scanning technique, an actuated electrical switch of the plurality of electrical switches corresponding to one of the plurality of buttons being pressed by the user. Subsequently, the at least one processor is configured to trigger an execution of the remote control action corresponding to the actuated electrical switch.

Another example embodiment is directed to a computer-implemented method for remotely controlling a media device. The computer-implemented method operates by detecting, by at least one processor and using an electrical matrix scanning technique, an actuated electrical switch corresponding to a remote control action for a media device. The actuated electrical switch has been actuated in response to a button of a remote control device being pressed by a user. The actuated electrical switch includes a first actuated electrode coupled to a first actuated electrical line of an electrical matrix, a second actuated electrode coupled to a second actuated electrical line of the electrical matrix, and a third actuated electrode coupled to a third actuated electrical line of the electrical matrix. Subsequently, the computer-implemented method operates by triggering, by the at least one processor and in response to detecting the actuated electrical switch, an execution of the remote control action corresponding to the actuated electrical switch.

### BRIEF DESCRIPTION OF THE FIGURES

The accompanying drawings are incorporated herein and form a part of the specification.

FIG. 1 illustrates a block diagram of a multimedia environment, according to some embodiments.

FIG. 2 illustrates a block diagram of a streaming media device, according to some embodiments.

FIG. 3 is a block diagram of a remote control device, according to some embodiments.

FIGS. 4A and 4B illustrate an example electrical matrix, according to some embodiments.

FIGS. 5A, 5B, and 5C illustrate another example electrical matrix, according to some embodiments.

FIG. 6 illustrates another example electrical matrix, according to some embodiments.

FIG. 7 is a flowchart illustrating a process for remotely controlling a media device, according to some embodiments.

FIG. 8 illustrates an example computer system useful for implementing various embodiments.

In the drawings, like reference numbers generally indicate identical or similar elements. Additionally, generally, the left-most digit(s) of a reference number identifies the drawing in which the reference number first appears.

### DETAILED DESCRIPTION

Provided herein are system, apparatus, device, method and/or computer program product embodiments, and/or combinations and sub-combinations thereof, for using electrical button matrix scanning techniques to detect remote control buttons pressed by users. For example, the system, apparatus, article of manufacture, method and/or computer program product embodiments disclosed herein, and/or combinations and sub-combinations thereof, can increase the number of buttons on the remote control without increasing the number of GPIO pins on the inside of the remote control, such as by converting a 2D scanning matrix into a three-dimensional (3D) scanning matrix by adding “pages”; combining simultaneous button presses and counting them as a unique event; or adding extension rows and columns to a 2D scanning matrix.

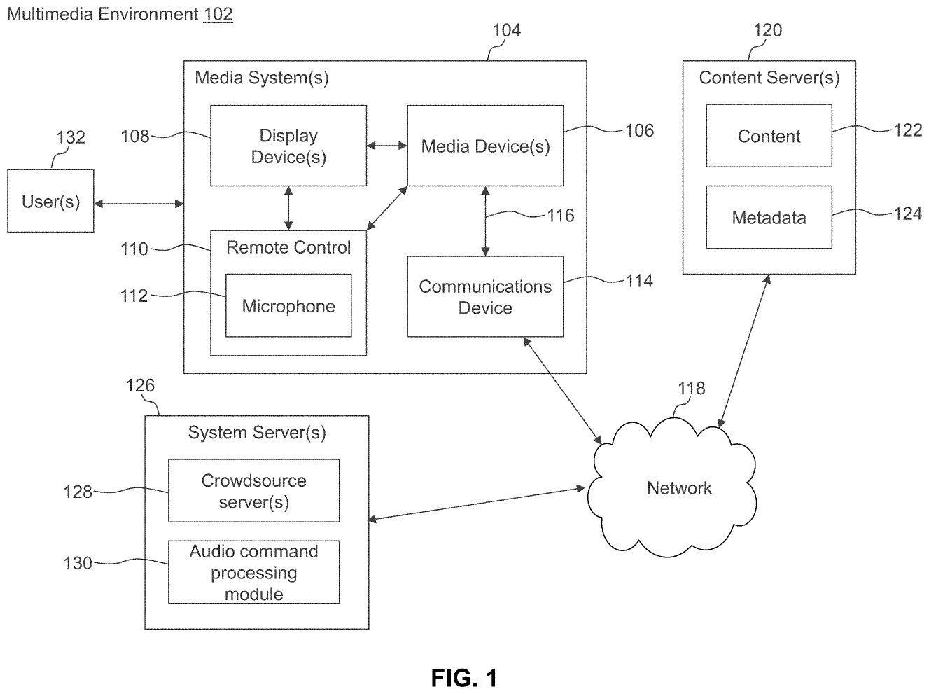

Various embodiments of this disclosure may be implemented using and/or may be part of a multimedia environment 102 shown in FIG. 1. It is noted, however, that multimedia environment 102 is provided solely for illustrative purposes, and is not limiting. Embodiments of this disclosure may be implemented using and/or may be part of environments different from and/or in addition to the multimedia environment 102, as will be appreciated by persons skilled in the relevant art(s) based on the teachings contained herein. An example of the multimedia environment 102 shall now be described.

Example Multimedia Environment

FIG. 1 illustrates a block diagram of a multimedia environment 102, according to some embodiments. In a non-limiting example, multimedia environment 102 may be directed to streaming media. However, this disclosure is applicable to any type of media (instead of or in addition to streaming media), as well as any mechanism, means, protocol, method and/or process for distributing media.

The multimedia environment 102 may include one or more media systems 104. A media system 104 could represent a family room, a kitchen, a backyard, a home theater, a school classroom, a library, a car, a boat, a bus, a plane, a movie theater, a stadium, an auditorium, a park, a bar, a restaurant, or any other location or space where it is desired to receive and play streaming content. User(s) 132 may operate with the media system 104 to select and consume content.

Each media system 104 may include one or more media devices 106 each coupled to one or more display devices 108. It is noted that terms such as “coupled,” “connected to,” “attached,” “linked,” “combined” and similar terms may refer to physical, electrical, magnetic, logical, etc., connections, unless otherwise specified herein.

Media device 106 may be a streaming media device, DVD or BLU-RAY device, audio/video playback device, cable box, and/or digital video recording device, to name just a few examples. Display device 108 may be a monitor, television (TV), computer, smart phone, tablet, wearable (such as a watch or glasses), appliance, internet of things (IoT) device, and/or projector, to name just a few examples. In some embodiments, media device 106 can be a part of, integrated with, operatively coupled to, and/or connected to its respective display device 108.

Each media device 106 may be configured to communicate with network 118 via a communications device 114. The communications device 114 may include, for example, a cable modem or satellite TV transceiver. The media device 106 may communicate with the communications device 114 over a link 116, wherein the link 116 may include wireless (such as WiFi) and/or wired connections.

In various embodiments, the network 118 can include, without limitation, wired and/or wireless intranet, extranet, Internet, cellular, Bluetooth, infrared, and/or any other short range, long range, local, regional, global communications mechanism, means, approach, protocol and/or network, as well as any combination(s) thereof.

Media system 104 may include a remote control device 110. The remote control device 110 can be any component, part, apparatus and/or method for controlling the media device 106 and/or display device 108, such as a remote control, a tablet, laptop computer, smartphone, wearable, on-screen controls, integrated control buttons, audio controls, or any combination thereof, to name just a few examples. In an embodiment, the remote control device 110 wirelessly communicates with the media device 106 and/or display device 108 using cellular, Bluetooth, infrared, etc., or any combination thereof. The remote control device 110 may include a microphone 112, which is further described below.

The multimedia environment 102 may include a plurality of content servers 120 (also called content providers or sources). Although only one content server 120 is shown in FIG. 1, in practice the multimedia environment 102 may include any number of content servers 120. Each content server 120 may be configured to communicate with network 118.

Each content server 120 may store content 122 and metadata 124. Content 122 may include any combination of music, videos, movies, TV programs, multimedia, images, still pictures, text, graphics, gaming applications, advertisements, programming content, public service content, government content, local community content, software, and/or any other content or data objects in electronic form.

In some embodiments, metadata 124 includes data about content 122. For example, metadata 124 may include associated or ancillary information indicating or related to writer, director, producer, composer, artist, actor, summary, chapters, production, history, year, trailers, alternate versions, related content, applications, and/or any other information pertaining or relating to the content 122. Metadata 124 may also or alternatively include links to any such information pertaining or relating to the content 122. Metadata 124 may also or alternatively include one or more indexes of content 122, such as but not limited to a trick mode index.

The multimedia environment 102 may include one or more system servers 126. The system servers 126 may operate to support the media devices 106 from the cloud. It is noted that the structural and functional aspects of the system servers 126 may wholly or partially exist in the same or different ones of the system servers 126.

The media devices 106 may exist in thousands or millions of media systems 104. Accordingly, the media devices 106 may lend themselves to crowdsourcing embodiments and, thus, the system servers 126 may include one or more crowdsource servers 128. For example, using information received from the media devices 106 in the thousands and millions of media systems 104, the crowdsource server(s) 128 may identify similarities and overlaps between closed captioning requests issued by different users 132 watching a particular movie. Based on such information, the crowdsource server(s) 128 may determine that turning closed captioning on may enhance users' viewing experience at particular portions of the movie (for example, when the soundtrack of the movie is difficult to hear), and turning closed captioning off may enhance users' viewing experience at other portions of the movie (for example, when displaying closed captioning obstructs critical visual aspects of the movie). Accordingly, the crowdsource server(s) 128 may operate to cause closed captioning to be automatically turned on and/or off during future streamings of the movie.

The system servers 126 may also include an audio command processing module 130. As noted above, the remote control device 110 may include a microphone 112. The microphone 112 may receive audio data from users 132 (as well as other sources, such as the display device 108). In some embodiments, the media device 106 may be audio responsive, and the audio data may represent verbal commands from the user 132 to control the media device 106 as well as other components in the media system 104, such as the display device 108.

In some embodiments, the audio data received by the microphone 112 in the remote control device 110 is transferred to the media device 106, which is then forwarded to the audio command processing module 130 in the system servers 126. The audio command processing module 130 may operate to process and analyze the received audio data to recognize the user 132's verbal command. The audio command processing module 130 may then forward the verbal command back to the media device 106 for processing.

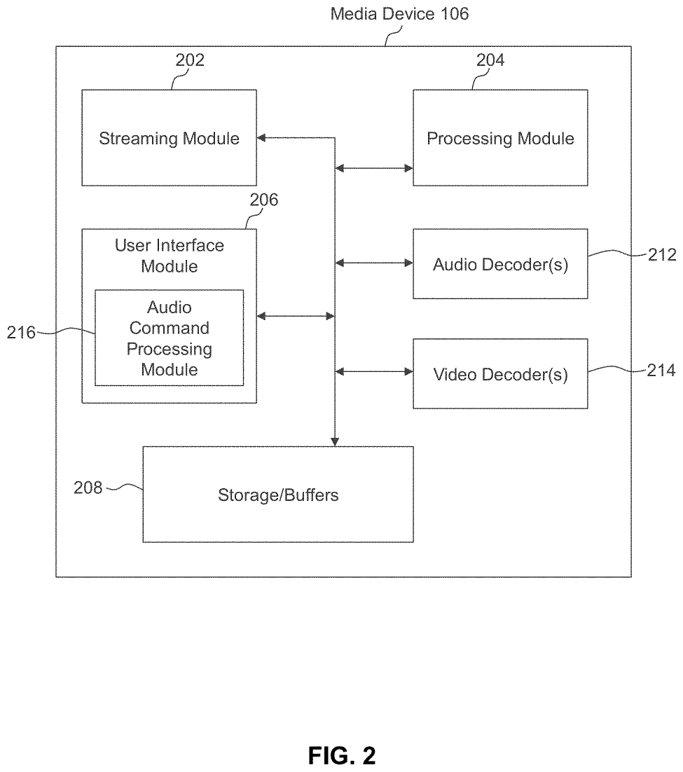

In some embodiments, the audio data may be alternatively or additionally processed and analyzed by an audio command processing module 216 in the media device 106 (see FIG. 2). The media device 106 and the system servers 126 may then cooperate to pick one of the verbal commands to process (either the verbal command recognized by the audio command processing module 130 in the system servers 126, or the verbal command recognized by the audio command processing module 216 in the media device 106).

FIG. 2 illustrates a block diagram of an example media device 106, according to some embodiments. Media device 106 may include a streaming module 202, processing module 204, storage/buffers 208, and user interface module 206. As described above, the user interface module 206 may include the audio command processing module 216.

The media device 106 may also include one or more audio decoders 212 and one or more video decoders 214. Each audio decoder 212 may be configured to decode audio of one or more audio formats, such as but not limited to AAC, HE-AAC, AC3 (Dolby Digital), EAC3 (Dolby Digital Plus), WMA, WAV, PCM, MP3, OGG GSM, FLAC, AU, AIFF, and/or VOX, to name just some examples. Similarly, each video decoder 214 may be configured to decode video of one or more video formats, such as but not limited to MP4 (mp4, m4a, m4v, f4v, f4a, m4b, m4r, f4b, mov), 3GP (3gp, 3gp2, 3g2, 3gpp, 3gpp2), OGG (ogg, oga, ogv, ogx), WMV (wmv, wma, asf), WEBM, FLV, AVI, QuickTime, HDV, MXF (OPla, OP-Atom), MPEG-TS, MPEG-2 PS, MPEG-2 TS, WAV, Broadcast WAV, LXF, GXF, and/or VOB, to name just some examples. Each video decoder 214 may include one or more video codecs, such as but not limited to H.263, H.264, H.265, HEV, MPEG1, MPEG2, MPEG-TS, MPEG-4, Theora, 3GP, DV, DVCPRO, DVCPRO, DVCProHD, IMX, XDCAM HD, XDCAM HD422, and/or XDCAM EX, to name just some examples.

Now referring to both FIGS. 1 and 2, in some embodiments, the user 132 may interact with the media device 106 via, for example, the remote control device 110. For example, the user 132 may use the remote control device 110 to interact with the user interface module 206 of the media device 106 to select content, such as a movie, TV show, music, book, application, game, etc. The streaming module 202 of the media device 106 may request the selected content from the content server(s) 120 over the network 118. The content server(s) 120 may transmit the requested content to the streaming module 202. The media device 106 may transmit the received content to the display device 108 for playback to the user 132.

In streaming embodiments, the streaming module 202 may transmit the content to the display device 108 in real time or near real time as it receives such content from the content server(s) 120. In non-streaming embodiments, the media device 106 may store the content received from content server(s) 120 in storage/buffers 208 for later playback on display device 108.

Example Remote Control Device

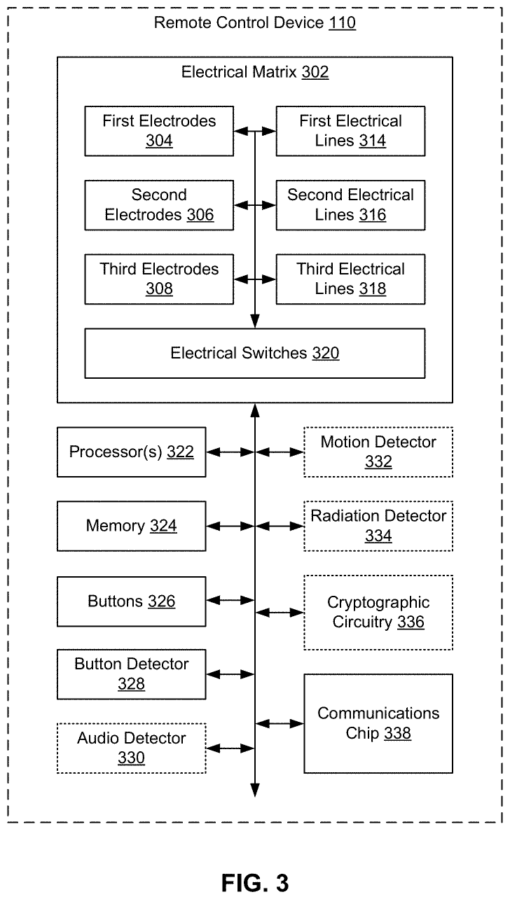

FIG. 3 illustrates an example block diagram of remote control device 110 for controlling a media device 106, according to some embodiments. Remote control device 110 can include an electrical matrix 302 coupled to one or more processors 322, a memory 324, and a plurality of buttons 326, among other hardware. The electrical matrix 302 can include a first plurality of electrodes 304 disposed on a substrate (e.g., built into and/or soldered onto a printed circuit board (PCB)) and electrically coupled to a first plurality of electrical lines 314, a second plurality of electrodes 306 disposed on the substrate and electrically coupled to a second plurality of electrical lines 316, and a third plurality of electrodes 308 disposed on the substrate and electrically coupled to a third plurality of electrical lines 318. In some aspects, the electrical matrix 302 can be formed on a PCB.

In various embodiments, the electrical matrix 302 can include a row-column scanning matrix. The electrical matrix 302 may be or include, for example, a 2D scanning matrix, a 3D scanning matrix, a multi-row encoding matrix, a row-column extension matrix, any other suitable structure, or any combination thereof.

In one example, the electrical matrix 302 can include a 2D scanning matrix having column electrodes connected to column electrical lines and row electrodes connected to row electrical lines. In this first example, the first plurality of electrodes 304 can include a plurality of column electrodes, the first plurality of electrical lines 314 can include a plurality of column electrical lines, the second plurality of electrodes 306 can include a plurality of row electrodes, and the second plurality of electrical lines 316 can include a plurality of row electrical lines.

As used herein, the term “electrical switch” refers to the electrodes built into a PCB or a physical switch component that is soldered to a PCB. As used herein, the term “button” refers to the entire button system including the physical button touchable by a user and the electrical switch disposed underneath the physical button, which is the device that makes the actual electrical contact in the circuit, be it a component or built into the PCB.

In the 2D scanning matrix embodiment disclosed herein, for r row signals and c column signals, the total number of buttons detectable is r×c, and the total number of GPIO signals needed is r+c. For example, for 2D scanning matrix having 5 rows and 5 columns, the total number of buttons detectable is 5×5=25 buttons and the total number of GPIO signals needed is 5+5=10 signals.

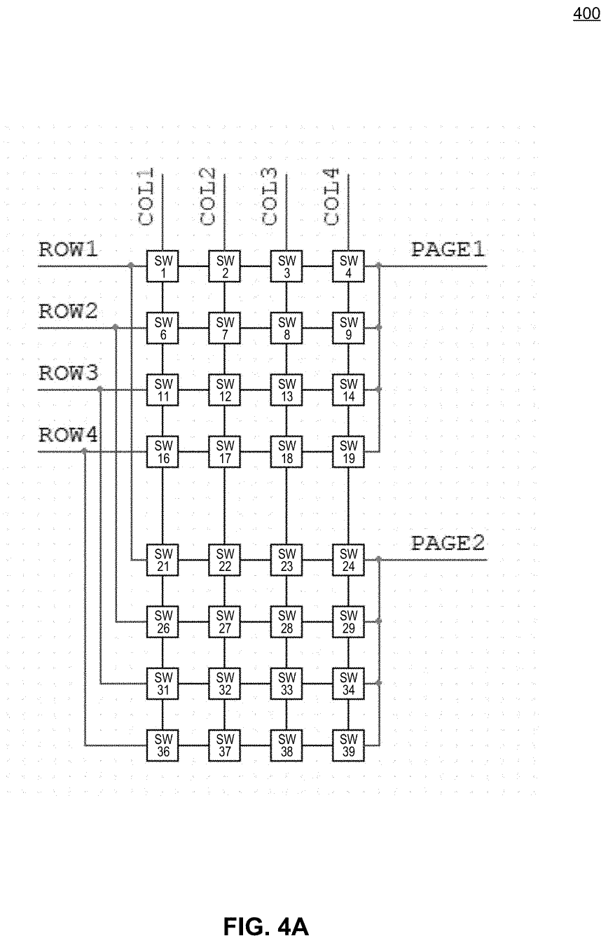

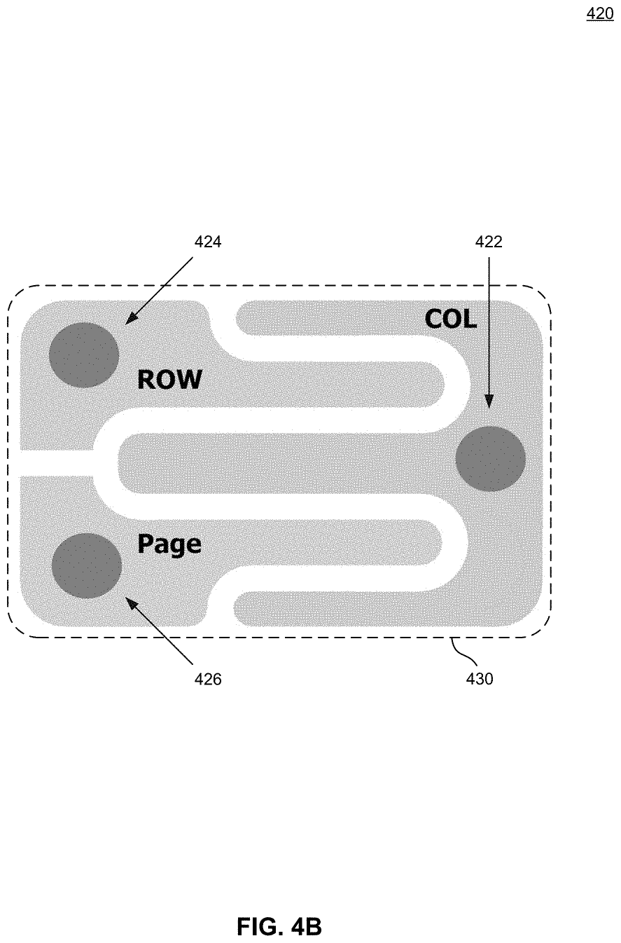

In another example (e.g., as shown in FIGS. 4A and 4B), the electrical matrix 302 can include a 3D scanning matrix having column electrodes connected to column electrical lines, row electrodes connected to row electrical lines, and page electrodes connected to page electrical lines (e.g., one additional GPIO signal per page; each electrical switch has a third electrical contact to a separate GPIO input to indicate which page the active button press is on). In this second example, the first plurality of electrodes 304 can include a plurality of column electrodes, the first plurality of electrical lines 314 can include a plurality of column electrical lines, the second plurality of electrodes 306 can include a plurality of row electrodes, the second plurality of electrical lines 316 can include a plurality of row electrical lines, the third plurality of electrodes 308 can include a plurality of page electrodes, and the third plurality of electrical lines 318 can include a plurality of page electrical lines.

In some embodiments, the 3D scanning matrix may utilize a 2D scanning matrix and add scanning matrix “pages.” For example, each electrical switch can have a third electrical contact to a separate GPIO input to indicate which page the active button press is on. In some embodiments, one additional GPIO signal may be utilized for each page.

In the 3D scanning matrix embodiment disclosed herein, for r row signals, c column signals, and p page signals, the total number of buttons detectable is (r×c)×p, and the total number of GPIO signals needed is r+c+p. For example, for a 3D scanning matrix having 5 rows, 5 columns, and 3 pages, the total number of buttons detectable is (5×5)×3=75 buttons and the total number of GPIO signals needed is 5+5+3=13 signals.

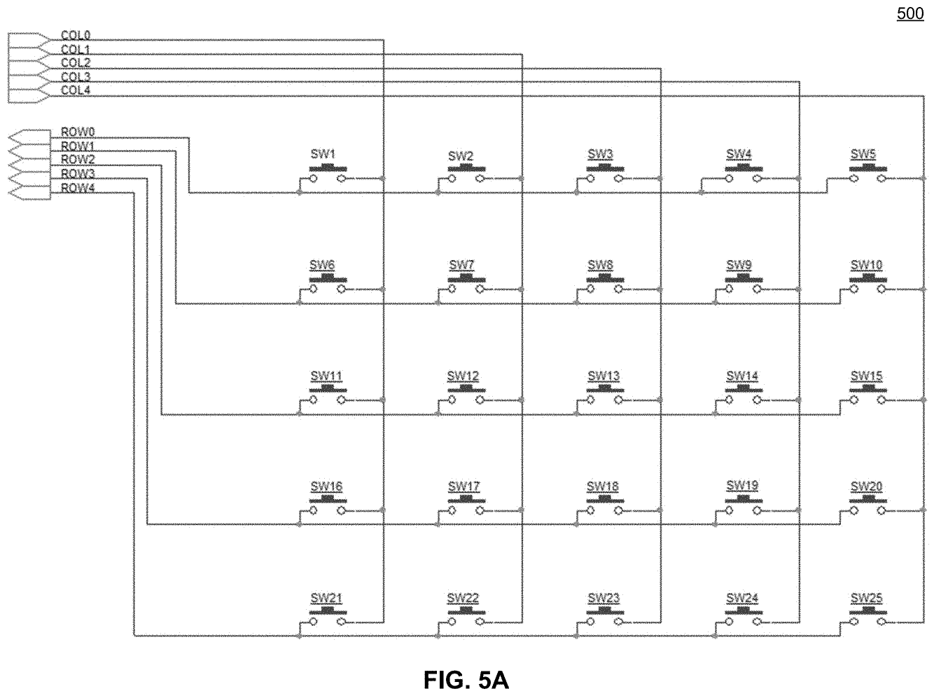

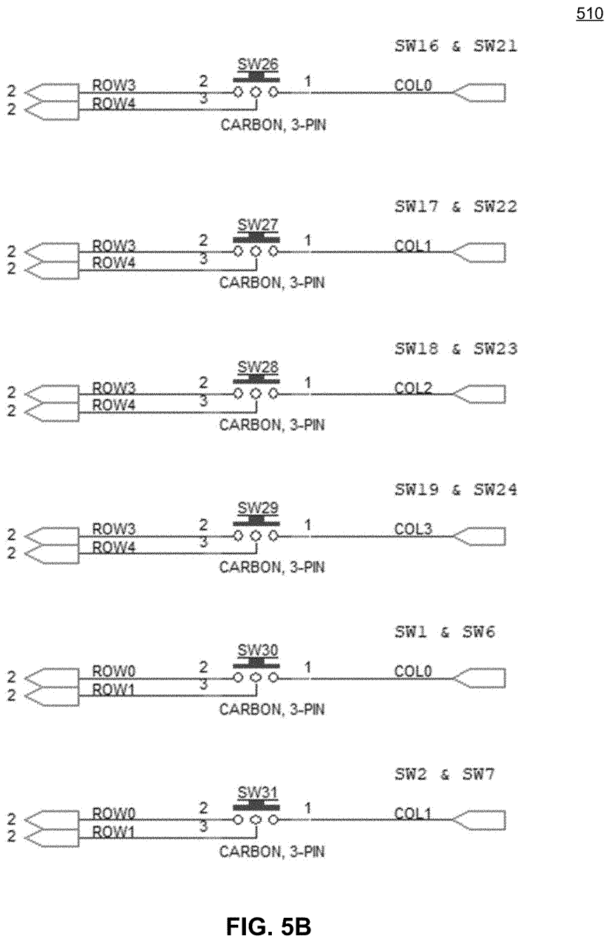

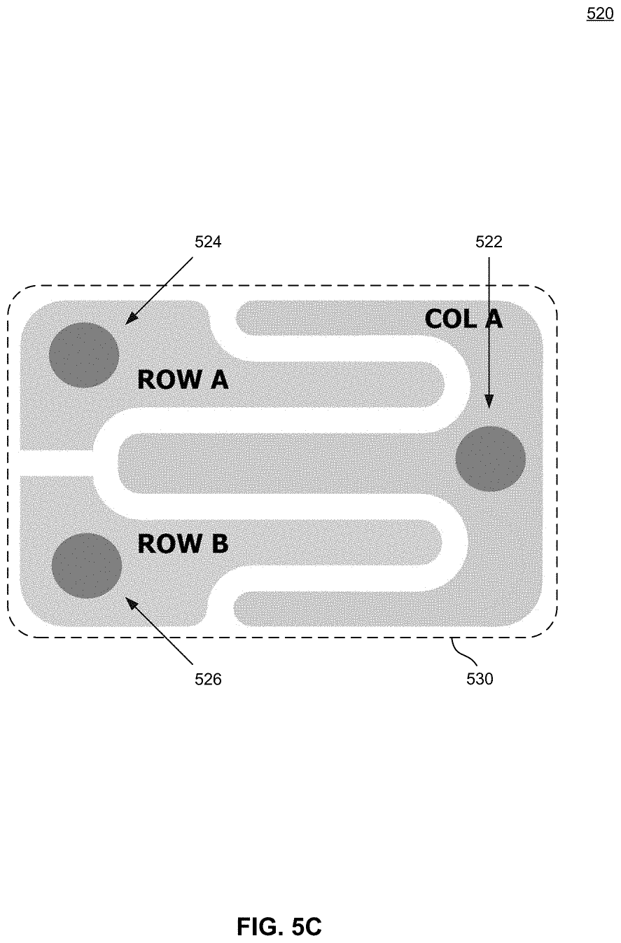

In yet another example (e.g., as shown in FIGS. 5A, 5B, and 5C), the electrical matrix 302 can include a multi-row encoding matrix having column electrodes connected to column electrical lines, first row electrodes connected to first row electrical lines, and second row electrodes connected to second row electrical lines configured to simulate two of the plurality of buttons 326 being simultaneously pressed by the user. In this third example, the first plurality of electrodes 304 can include a plurality of column electrodes, the first plurality of electrical lines 314 can include a plurality of column electrical lines, the second plurality of electrodes 306 can include a first plurality of row electrodes, the second plurality of electrical lines 316 can include a second plurality of row electrical lines, the third plurality of electrodes 308 can include a second plurality of row electrodes, and the third plurality of electrical lines 318 can include a second plurality of row electrical lines.

In some embodiments, the multi-row encoding matrix may utilize a 2D scanning matrix and further simulate two simultaneous button presses which may be detected by the button detector 328 as unique events. For instance, one physical button (e.g., the numeral “1”) when pressed by a user may simultaneously activate two row electrical lines on the same column electrical line as if two different buttons (e.g., home and mute) were simultaneously pressed by the user, and, as a result, the button detector 328 may detect the actuated electrical switch positioned below the pressed physical button (e.g., the numeral “1”) rather than the two electrical switches positioned below the two physical buttons (e.g., home and mute) whose actuation was simulated. In some embodiments, no more than two rows may be activated for better reliability, and only for buttons on the same column electrical line.

In the multi-row encoding matrix embodiment disclosed herein, for r row signals and c column signals, with 2 of the r rows activated as if they were simultaneous button presses, the total number of buttons detectable is c×{r+[r×(r−1)]/2}, and the total number of GPIO signals needed is r+c. For example, for a multi-row encoding matrix having 5 rows and 5 columns, with 2 of the 5 rows activated as if they were simultaneous button presses, the total number of buttons detectable is 5×{5+[5×(5−1)]/2}=75 buttons and the total number of GPIO signals needed is 5+5=10 signals.

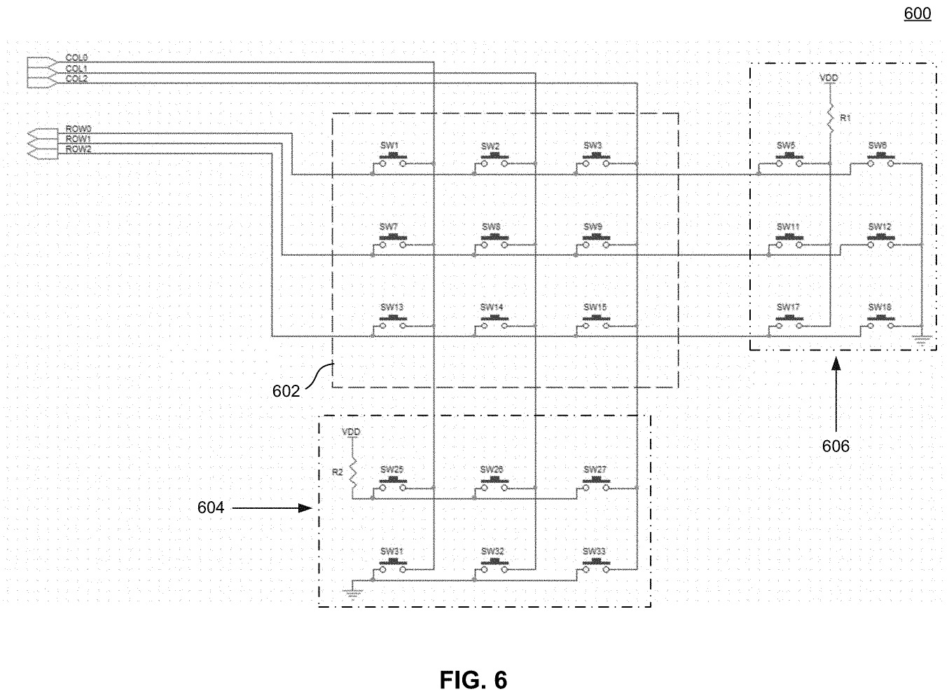

In still another example (e.g., as shown in FIG. 6), the electrical matrix 302 can include a row-column extension matrix having column electrodes connected to column electrical lines, row electrodes connected to row electrical lines, extension column electrodes connected to additional column electrical lines, and extension row electrodes connected to additional row electrical lines. In this fourth example, the first plurality of electrodes 304 can include a plurality of column electrodes, the first plurality of electrical lines 314 can include a plurality of column electrical lines, the second plurality of electrodes 306 can include a plurality of row electrodes, the second plurality of electrical lines 316 can include a plurality of row electrical lines, the third plurality of electrodes 308 can include a plurality of column extension electrodes and row extension electrodes, and the third plurality of electrical lines 318 can include a plurality of column extension electrical lines and row extension electrical lines. The extension column electrical lines, extension row electrical lines, or both can be pulled to logic high or low and not connected to the electrical matrix 302 in a different manner than the non-extension row and column electrical lines.

In some embodiments, the row-column extension matrix may utilize a 2D scanning matrix and add two additional rows and two additional columns of buttons. In some embodiments, each additional row or column may be pulled to logic high or low and not be connected to the matrix in the same way as the rows and columns in the primary 2D scanning matrix.

In the row-column extension matrix embodiment disclosed herein, for r row signals and c column signals, with 2 additional rows and 2 additional columns of buttons, the total number of buttons detectable is (r×c)+2r+2c, and the total number of GPIO signals needed is r+c. For example, for a row-column extension matrix having 5 rows and 5 columns, with 2 additional rows and 2 additional columns, the total number of buttons detectable is (5×5)+(2×5)+(2×5)=45 buttons and the total number of GPIO signals needed is 5+5=10 signals.

An example comparison of various electrical matrix embodiments disclosed herein is shown below in Table 1:

TABLE 1
Example comparison of various electrical matrix
embodiments disclosed herein.

| | Maximum Number of |
|---|---|
| | Buttons Detectable with 13 |
| Electrical Matrix Embodiment | GPIO Signals Available |
| Dedicated GPIO signal per button | 13 |
| 2D Scanning Matrix | 42 |
| 3D Scanning Matrix | 75 |
| (e.g., FIGS. 4A and 4B) | |
| Multi-Row Encoding Matrix | 168 |
| (e.g., FIGS. 5A, 5B, and 5C) | |
| Row-Column Extension Matrix | 68 |
| (e.g., FIG. 6) | |

The electrical matrix 302 can further include a plurality of electrical switches 320 corresponding to a plurality of remote control actions for a media device 106. Each electrical switch of the plurality of electrical switches 320 can include a respective first electrode of the first plurality of electrodes 304, a respective second electrode of the second plurality of electrodes 306, and a respective third electrode of the third plurality of electrodes 308. Each electrical switch of the plurality of electrical switches 320 can correspond to a respective remote control action of the plurality of remote control actions. The plurality of remote control actions can include, but are not limited to, for example, power on/off, source, home, back/return, directional pad (dpad) up/down/left/right, select/enter (e.g., “OK”), volume up/down, mute, channel up/down, play/pause, fast forward, rewind, instant replay (e.g., replay last 15 seconds of streaming media content), options (e.g., “*”) sleep, channel/application quick launch (e.g., channel/application shortcuts), voice search/command, gaming actions (e.g., “A”; “B”; “X”; “Y”), any other suitable electronic action or command, and any combination thereof.

Remote control device 110 can further include a plurality of buttons 326 associated with (e.g., disposed over or above) the plurality of electrical switches 320. For example, each of the plurality of buttons 326 can be disposed over three electrodes: a respective first electrode of the first plurality of electrodes 304; a respective second electrode of the second plurality of electrodes 306; and a respective third electrode of the third plurality of electrodes 308. In response to being pressed by a user, each button in the plurality of buttons 326 can be configured to actuate a respective electrical switch of the plurality of electrical switches 320 (e.g., by contacting the three electrodes of the respective electrical switch).

Remote control device 110 can further include one or more processors 322, memory 324, buttons 326 (e.g., one or more physical buttons, virtual buttons, soft buttons, touchscreen areas, augmented reality (AR) buttons, virtual reality (VR) buttons, any other suitable buttons, or any combination thereof), button detector 328 (e.g., configured to detect buttons pressed by a user), audio detector 330 (e.g., microphone, microphone array), motion detector 332 (e.g., accelerometer, gyroscope, motion sensor), radiation detector 334 (e.g., photodetector, infrared (IR) sensor), cryptographic circuitry 336, communications chip 338, an audio transmitter (e.g., speaker), one or more radiation emitters (e.g., IR emitter), any other suitable hardware or software, or any combination thereof. Communications chip 338 may be an integrated circuit (IC), application specific IC (ASIC), programmable logic device (PLD), field programmable gate array (FPGA), or any other suitable chip including one or more transmitters, receivers, memories, any other suitable circuitry or structures, or any combination thereof. The one or more memories of the communications chip 338 may include a unique identifier (e.g., a scalable, preprogrammed 32-bit, 48-bit, 64-bit, 128-bit, 256-bit, or other-bit serial number), cryptographic data (e.g., a key, certificate, secret, or shared secret), any other suitable electronic information, or any combination thereof.

Referring now to FIGS. 1, 2, and 3, in some embodiments, a user may use remote control device 110 to interact with user interface module 206 of media device 106 to select content 122, such as a movie, TV show, music, book, application, game, or other content. Streaming module 202 of media device 106 may request the selected content 122 from one or more content servers 120 over communications network 118. One or more content servers 120 may transmit the requested content 122 to streaming module 202. Media device 106 may transmit the received content 122 to display device 108 for presentation to a user 132 of a user device. In streaming embodiments, streaming module 202 may transmit the content 122 to display device 108 in real time or near real time as it receives such content 122 from one or more content servers 120. In non-streaming embodiments, media device 106 may buffer or store the content 122 received from one or more content servers 120 in storage/buffers 208 for later playback on display device 108.

Remote control device 110 can be configured to generate (e.g., by button detector 328, audio detector 330, motion detector 332, one or more processors 322, any other suitable circuitry or structures, or any combination thereof) electronic signals indicative of user commands based on the detection of an electrical switch that has been actuated in response to a user pressing a button disposed over the electrical switch. A user command may correspond to one or more pressed buttons, audio commands, gesture commands, any other suitable commands input, uttered, or motioned by a user, or any combination thereof.

In an embodiment, a user may enter commands on remote control device 110 by pressing one or more of buttons 326, such as channel up/down, volume up/down, play/pause/stop/rewind/fast forward, menu, up, down, left, right, to name just a few examples. In such a case, the electronic signal indicative of the user command may correspond to a “key_up” signal, a “key_down” signal, a “key_repeat” signal (e.g., when the user holds down a button continuously to scroll), a “key_repeat_stop” signal (e.g., based on a timeout value, such as 10.0 seconds), any other suitable signal, or any combination thereof. In such aspects, buttons 326, any circuitry or structures connected thereto, one or more processors 322, or a combination thereof may generate an electronic signal indicative of a button having been pressed by a user in response to the user pressing the button and buttons 326, any circuitry or structures connected thereto, one or more processors 322, or a combination thereof detecting a change in an electrical resistance, impedance, or capacitance associated with the pressed button.

Remote control device 110 can be configured to detect (e.g., by the one or more processors 322 using an electrical matrix scanning technique executed by the button detector 328) an actuated electrical switch of the plurality of electrical switches 320 corresponding to one of the plurality of buttons 326 being pressed by the user. The electrical matrix scanning technique can include, for example, a row-column scanning technique, a 3D scanning technique, a multi-row encoding scanning technique, a row-column extension scanning technique, any other suitable technique, and any combinations or sub-combinations thereof. For example, to detect the actuated electrical switch, the one or more processors 322 can be configured to utilize the button detector 328 to execute an electrical matrix scanning technique that includes: (i) sequentially applying an electrical voltage to each electrical line of the first plurality of electrical lines 314 to detect a first actuated electrical line of the first plurality of electrical lines 314 corresponding to a first actuated electrode of the first plurality of electrodes 304; (ii) scanning each electrical line of the second plurality of electrical lines 316 to detect a second actuated electrical line of the second plurality of electrical lines 316 corresponding to a second actuated electrode of the second plurality of electrodes 306; (iii) scanning each electrical line of the third plurality of electrical lines 318 to detect a third actuated electrical line of the third plurality of electrical lines 318 corresponding to a third actuated electrode of the third plurality of electrodes 308; and (iv) detecting the actuated electrical switch based on the first actuated electrical line, the second actuated electrical line, and the third actuated electrical line. Subsequently, the one or more processors 322 can be configured to trigger an execution of the remote control action corresponding to the actuated electrical switch (e.g., by transmitting a remote control action to the media device 106 via the communications chip 338).

Additionally or alternatively, in an embodiment, a user may enter commands on remote control device 110 by uttering a command within audible range of audio detector 330. For example, to increase the volume, the user may say “Volume Up.” To change to the immediately preceding channel, the user may say “Channel down.” In an embodiment, the user may say a trigger word before saying commands, to better enable remote control device 110 to distinguish between commands and other spoken words. For example, the trigger word may be “Command.” In this case, to increase the volume, the user may say “Command Volume Up.” In an embodiment, there may be one or more trigger words that are recognized by remote control device 110. In such aspects, one or more processors 322 may generate an electronic signal indicative of an audio command having been spoken by a user in response to the user speaking the audio command and audio detector 330, any circuitry or structures connected thereto, one or more processors 322, or a combination thereof detecting an audio signal associated with the command.

Additionally or alternatively, in an embodiment, a user may enter commands on remote control device 110 by making a gesture with remote control device 110. For example, to increase the volume, the user may move remote control device 110 in an upwards direction. To change to the immediately preceding channel, the user may move remote control device 110 in a counter-clockwise direction. In such aspects, one or more processors 322 may generate an electronic signal indicative of a gesture command having been made by a user in response to the user making the gesture command and motion detector 332, any circuitry or structures connected thereto, one or more processors 322, or a combination thereof detecting a movement associated with the command.

In an embodiment, remote control device 110 may be configured to encrypt (e.g., by cryptographic circuitry 336, one or more processors 322, any other suitable circuitry or structures, or any combination thereof) an electronic signal indicative of a user command based on a unique identifier, cryptographic data, any other suitable electronic information, or any combination thereof. Remote control device 110 may be configured to encrypt the electronic signal using a symmetric cryptographic technique, an asymmetric cryptographic technique, any other suitable cryptographic technique, or any combination thereof. Thereafter, media device 106 may be configured to receive and decrypt the encrypted electronic signal (e.g., based on cryptographic data stored in media device 106), and perform the action associated with the user command.

FIGS. 4A and 4B illustrate an example 3D scanning matrix 400. As shown in FIG. 4A, the example 3D scanning matrix 400 can include column electrodes connected to column electrical lines (e.g., “COL1”; “COL2”; “COL3”; “COL4”), row electrodes connected to row electrical lines (e.g., “ROW1”; “ROW2”; “ROW3”; “ROW4”), and page electrodes connected to page electrical lines (e.g., “PAGE1”; “PAGE2”). The example 3D scanning matrix 400 can further include electrical switches (e.g., “SW1” through “SW39”) corresponding to a plurality of remote control actions for a media device 106.

FIG. 4B shows an example physical implementation of an example 3D scanning, 3-terminal electrical switch on a PCB. As shown in FIG. 4B, each electrical switch 420 can include a respective column electrode 422 (“COL”) connected to a respective column electrical line, a respective row electrode 424 (“ROW”) connected to a respective row electrical line, and a respective page electrode 426 (“Page”) connected to a respective page electrical line (e.g., a separate GPIO input to indicate which page the active button press is on). A respective button 430 may be positioned over each electrical switch such that when a user presses a button, the button contacts a respective column electrode 422, row electrode 424, and page electrode 426 to actuate a respective electrical switch (e.g., SW24).

FIGS. 5A, 5B, and 5C illustrate an example multi-row encoding matrix 500. As shown in FIG. 5A, the example multi-row encoding matrix 500 can include column electrodes connected to column electrical lines (e.g., “COL0”; “COL1”; “COL2”; “COL3”; “COL4”), row electrodes connected to row electrical lines (e.g., “ROW0”; “ROW1”; “ROW2”; “ROW3”; “ROW4”). The example multi-row encoding matrix 500 can further include electrical switches (e.g., “SW1” through “SW25”) corresponding to a plurality of remote control actions for a media device 106.

As shown in FIG. 5B, the example multi-row encoding matrix 500 can further include additional electrical switches 510 (e.g., “SW26” through “SW31”), each of which simulates two simultaneously-pressed buttons that may be decoded as a unique pressed button. As a result, when a user presses a button disposed over one of the additional electrical switches 510, the electrical switch actuated by that pressed button is configured to simulate two of the plurality of buttons disposed over the electrical switches (e.g., “SW1” through “SW25”) shown in FIG. 5A being simultaneously pressed by the user. For example, the actuation of electrical switch “SW26” can be detected by the activation of “COL0,” “ROW3,” and “ROW4,” which simulates the simultaneous pressing of the two buttons disposed over electrical switches “SW16” and “SW21.” In another example, the actuation of electrical switch “SW27” can be detected by the activation of “COL1,” “ROW3,” and “ROW4,” which simulates the simultaneous pressing of the two buttons disposed over electrical switches “SW17” and “SW22.” In another example, the actuation of electrical switch “SW28” can be detected by the activation of “COL2,” “ROW3,” and “ROW4,” which simulates the simultaneous pressing of the two buttons disposed over electrical switches “SW18” and “SW23.” In another example, the actuation of electrical switch “SW29” can be detected by the activation of “COL3,” “ROW3,” and “ROW4,” which simulates the simultaneous pressing of the two buttons disposed over electrical switches “SW19” and “SW24.” In another example, the actuation of electrical switch “SW30” can be detected by the activation of “COL0,” “ROW0,” and “ROW1,” which simulates the simultaneous pressing of the two buttons disposed over electrical switches “SW1” and “SW6.” In another example, the actuation of electrical switch “SW31” can be detected by the activation of “COL1,” “ROW0,” and “ROW 1,” which simulates the simultaneous pressing of the two buttons disposed over electrical switches “SW2” and “SW7.”

FIG. 5C shows an example physical implementation of an example multi-row encoding, 3-terminal electrical switch on a PCB. As shown in FIG. 5C, each electrical switch 520 can include a respective column electrode 522 (“COL A”) connected to a respective column electrical line, a respective first row electrode 524 (“ROW A”) connected to a respective first row electrical line, and a respective second row electrode 526 (“ROW B”) connected to a respective second row electrical line. A respective button 530 may be positioned over each electrical switch such that when a user presses a button, the button contacts a respective column electrode 522, first row electrode 524, and second row electrode 526 to actuate a respective electrical switch (e.g., SW26).

FIG. 6 illustrates an example row-column extension matrix 600. As shown in FIG. 6A, the example row-column extension matrix 600 can include column electrodes connected to column electrical lines (e.g., “COL0”; “COL1”; “COL2”), row electrodes connected to row electrical lines (e.g., “ROW0”; “ROW1”; “ROW2”). The example row-column extension matrix 600 can further include a 3×3 matrix 602 of electrical switches (e.g., “SW1”; “SW2”; “SW3”; “SW7”; “SW8”; “SW9”; “SW13”; “SW14”; “SW15”) corresponding to a plurality of remote control actions for a media device 106. The example row-column extension matrix 600 can further include a column extension 604 having an additional six electrical switches (e.g., “SW25”; “SW26”; “SW27”; “SW31”; “SW32”; “SW33”). The example row-column extension matrix 600 can further include a row extension 606 having an additional six electrical switches (e.g., “SW5”; “SW6”; “SW11”; “SW12”; “SW17”; “SW18”). Each additional column or row of the column extension 604 and the row extension 606 may be pulled to logic high or low and connected to the 3×3 matrix 602 in a different way than the rows and columns of the 3×3 matrix 602.

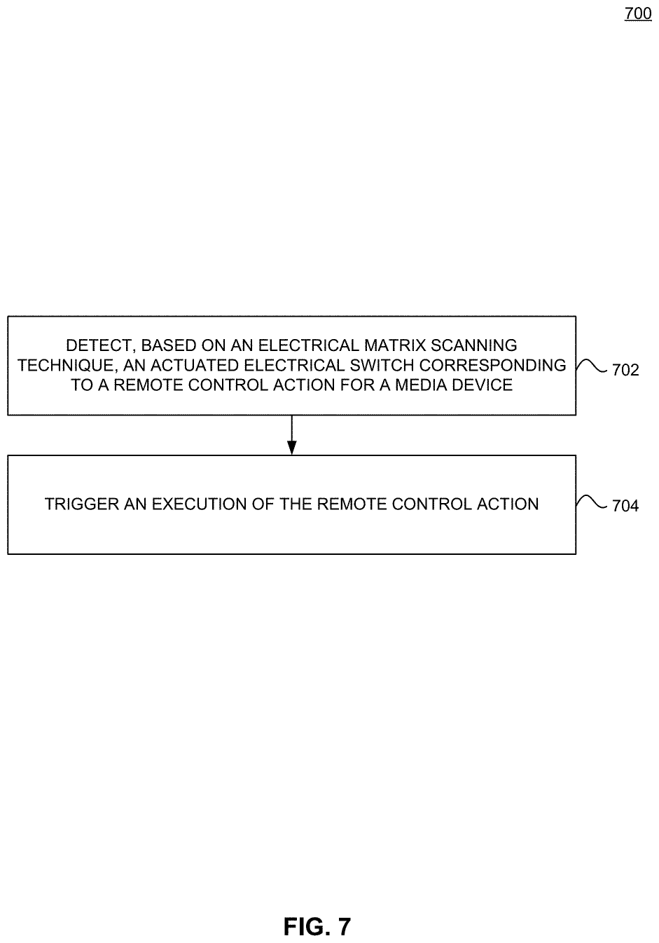

FIG. 7 is a flowchart for a method 700 for remotely controlling a media device, according to an embodiment. Method 700 can be performed by processing logic that can comprise hardware (e.g., circuitry, dedicated logic, programmable logic, microcode, etc.), software (e.g., instructions executing on a processing device), or a combination thereof. It is to be appreciated that not all steps may be needed to perform the disclosure provided herein. Further, some of the steps may be performed simultaneously, or in a different order than shown in FIG. 7, as will be understood by a person of ordinary skill in the art. Method 700 shall be described with reference to FIGS. 1 and 3. However, method 700 is not limited to those example embodiments.

In 702, remote control device 110 detects (e.g., by one or more processors 322, button detector 328, any other suitable hardware or software, or any combination thereof) an actuated electrical switch (e.g., an actuated one of the plurality of electrical switches 320) corresponding to a remote control action for a media device 106. For example, remote control device 110 may detect the actuated electrical switch using an electrical matrix scanning technique executed by the button detector 328. The actuated electrical switch may have been actuated in response to a button 326 of the remote control device 110 being pressed by a user. The actuated electrical switch may include a first actuated electrode (e.g., an actuated one of the first plurality of electrodes 304) coupled to a first actuated electrical line (e.g., an actuated one of the first plurality of electrical lines 314) of an electrical matrix 302, a second actuated electrode (e.g., an actuated one of the second plurality of electrodes 306) coupled to a second actuated electrical line (e.g., an actuated one of the second plurality of electrical lines 316) of the electrical matrix 302, and a third actuated electrode (e.g., an actuated one of the third plurality of electrodes 308) coupled to a third actuated electrical line (e.g., an actuated one of the third plurality of electrical lines 318) of the electrical matrix 302. The electrical matrix 302 may be, for example, a 3D scanning matrix, a multi-row encoding matrix, a row-column extension matrix, any other suitable structure, or any combination thereof.

In 704, remote control device 110 triggers (e.g., by one or more processors 322, any other suitable hardware or software, or any combination thereof), in response to detection of the actuated electrical switch at 702, an execution of the remote control action corresponding to the actuated electrical switch.

Example Computer System

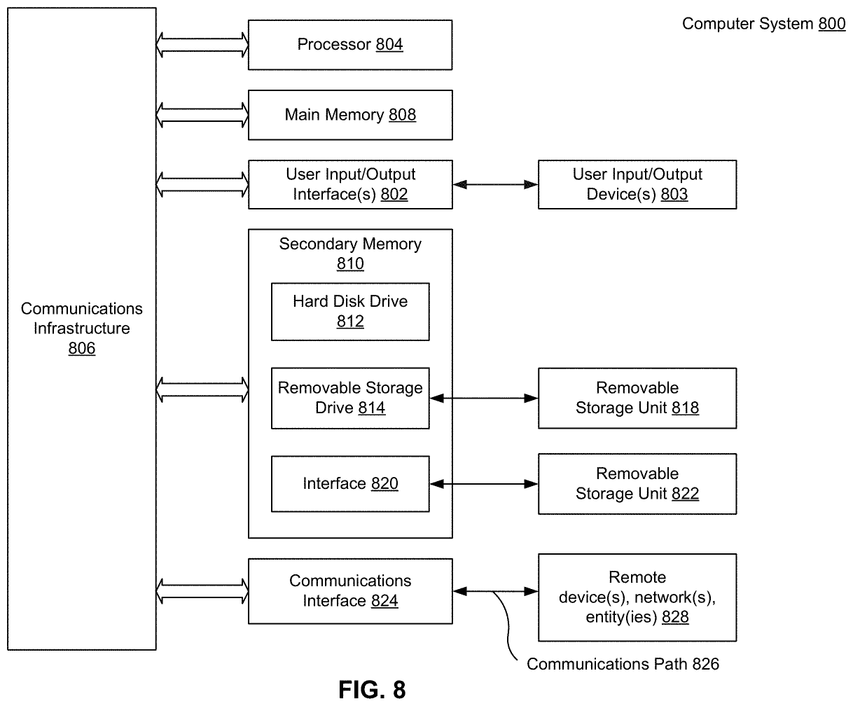

Various embodiments may be implemented, for example, using one or more computer systems, such as computer system 800 shown in FIG. 8. For example, the media device 106 may be implemented using combinations or sub-combinations of computer system 800. Also or alternatively, one or more computer systems 800 may be used, for example, to implement any of the embodiments discussed herein, as well as combinations and sub-combinations thereof.

Computer system 800 may include one or more processors (also called central processing units, or CPUs), such as one or more processors 804. In some embodiments, one or more processors 804 may be connected to a communications infrastructure 806 (e.g., a bus).

Computer system 800 may also include user input/output device(s) 803, such as monitors, keyboards, pointing devices, etc., which may communicate with communications infrastructure 806 through user input/output interface(s) 802.

One or more of processors 804 may be a graphics processing unit (GPU). In an embodiment, a GPU may be a processor that is a specialized electronic circuit designed to process mathematically intensive applications. The GPU may have a parallel structure that is efficient for parallel processing of large blocks of data, such as mathematically intensive data common to computer graphics applications, images, videos, etc.

Computer system 800 may also include a main memory 808 (e.g., a primary memory or storage device), such as random access memory (RAM). Main memory 808 may include one or more levels of cache. Main memory 808 may have stored therein control logic (e.g., computer software) and/or data.

Computer system 800 may also include one or more secondary storage devices or memories such as secondary memory 810. Secondary memory 810 may include, for example, a hard disk drive 812, a removable storage drive 814 (e.g., a removable storage device), or both. Removable storage drive 814 may be a floppy disk drive, a magnetic tape drive, a compact disk drive, an optical storage device, tape backup device, and/or any other storage device/drive.

Removable storage drive 814 may interact with a removable storage unit 818. Removable storage unit 818 may include a computer usable or readable storage device having stored thereon computer software (e.g., control logic) and/or data. Removable storage unit 818 may be a floppy disk, magnetic tape, compact disk, DVD, optical storage disk, and/any other computer data storage device. Removable storage drive 814 may read from and/or write to removable storage unit 818.

Secondary memory 810 may include other means, devices, components, instrumentalities or other approaches for allowing computer programs and/or other instructions and/or data to be accessed by computer system 800. Such means, devices, components, instrumentalities or other approaches may include, for example, a removable storage unit 822 and an interface 820. Examples of the removable storage unit 822 and the interface 820 may include a program cartridge and cartridge interface (such as that found in video game devices), a removable memory chip (such as an EPROM or PROM) and associated socket, a memory stick and USB or other port, a memory card and associated memory card slot, and/or any other removable storage unit and associated interface.

Computer system 800 may further include a communications interface 824 (e.g., a network interface). Communications interface 824 may enable computer system 800 to communicate and interact with any combination of external devices, external networks, external entities, etc. (individually and collectively referenced by reference number 828). For example, communications interface 824 may allow computer system 800 to communicate with external devices 828 (e.g., remote devices) over communications path 826, which may be wired and/or wireless (or a combination thereof), and which may include any combination of LANs, WANs, the Internet, etc. Control logic and/or data may be transmitted to and from computer system 800 via communications path 826.

Computer system 800 may also be any of a personal digital assistant (PDA), desktop workstation, laptop or notebook computer, netbook, tablet, smart phone, smart watch or other wearable, appliance, part of the Internet-of-Things, and/or embedded system, to name a few non-limiting examples, or any combination thereof.

Computer system 800 may be a client or server, accessing or hosting any applications and/or data through any delivery paradigm, including but not limited to remote or distributed cloud computing solutions; local or on-premises software (“on-premise” cloud-based solutions); “as a service” models (e.g., content as a service (CaaS), digital content as a service (DCaaS), software as a service (SaaS), managed software as a service (MSaaS), platform as a service (PaaS), desktop as a service (DaaS), framework as a service (FaaS), backend as a service (BaaS), mobile backend as a service (MBaaS), infrastructure as a service (IaaS), etc.); and/or a hybrid model including any combination of the foregoing examples or other services or delivery paradigms.

Any applicable data structures, file formats, and schemas in computer system 800 may be derived from standards and specifications associated with images, audio, video, streaming (e.g., adaptive bitrate (ABR) streaming, content feeds), high-dynamic-range (HDR) video, text (e.g., closed captioning, subtitles), metadata (e.g., content metadata), data interchange, data serialization, data markup, digital rights management (DRM), encryption, any other suitable function or purpose, or any combination thereof. Alternatively, proprietary data structures, formats or schemas may be used, either exclusively or in combination with another standard or specification.

Standards and specifications associated with images may include, but are not limited to, Base Index Frames (BIF), Bitmap (BMP), Graphical Interchange Format (GIF), Joint Photographic Experts Group (JPEG or JPG), Portable Network Graphics (PNG), any other suitable techniques (e.g., functionally similar representations), any predecessors, successors, and variants thereof, and any combinations thereof.

Standards and specifications associated with audio may include, but are not limited to, Advanced Audio Coding (AAC), AAC High Efficiency (AAC-HE), AAC Low Complexity (AAC-LC), Apple Lossless Audio Codec (ALAC), Audio Data Transport Stream (ADTS), Audio Interchange File Format (AIFF), Digital Theater Systems (DTS), DTS Express (DTSE), Dolby Digital (DD or AC3), Dolby Digital Plus (DD+ or Enhanced AC3 (EAC3)), Dolby AC4, Dolby Atmos, Dolby Multistream (MS12), Free Lossless Audio Codec (FLAC), Linear Pulse Code Modulation (LPCM or PCM), Matroska Audio (MKA), Moving Picture Experts Group (MPEG)-1 Part 3 and MPEG-2 Part 3 (MP3), MPEG-4 Audio (e.g., MP4A or M4A), Ogg, Ogg with Vorbis audio (Ogg Vorbis), Opus, Vorbis, Waveform Audio File Format (WAVE or WAV), Windows Media Audio (WMA), any other suitable techniques, any predecessors, successors, and variants thereof, and any combinations thereof.

Standards and specifications associated with video may include, but are not limited to, Alliance for Open Media (AOMedia) Video 1 (AV1), Audio Video Interleave (AVI), Matroska Video (MKV), MPEG-4 Part 10 Advanced Video Coding (AVC or H.264), MPEG-4 Part 14 (MP4), MPEG-4 Video (e.g., MP4V or M4V), MPEG-H Part 2 High Efficiency Video Coding (HEVC or H.265), QuickTime File Format (QTFF or MOV), VP8, VP9, WebM, Windows Media Video (WMV), any other suitable techniques, any predecessors, successors, and variants thereof, and any combinations thereof.

Standards and specifications associated with streaming may include, but are not limited to, Adaptive Streaming over HTTP, Common Media Application Format (CMAF), Direct Publisher JavaScript Object Notation (JSON), HD Adaptive Streaming, HTTP Dynamic Streaming, HTTP Live Streaming (HLS), HTTP Secure (HTTPS), Hypertext Transfer Protocol (HTTP), Internet Information Services (IIS) Smooth Streaming (SMOOTH), Media RSS (MRSS), MPEG Dynamic Adaptive Streaming over HTTP (MPEG-DASH or DASH), MPEG transport stream (MPEG-TS or TS), Protected Interoperable File Format (PIFF), Scalable HEVC (SHVC), any other suitable techniques, any predecessors, successors, and variants thereof, and any combinations thereof.

Standards and specifications associated with HDR video may include, but are not limited to, Dolby Vision, HDR10 Media Profile (HDR10), HDR10 Plus (HDR10+), Hybrid Log-Gamma (HLG), Perceptual Quantizer (PQ), SL-HDR1, any other suitable techniques, any predecessors, successors, and variants thereof, and any combinations thereof.

Standards and specifications associated with text, metadata, data interchange, data serialization, and data markup may include, but are not limited to, Internet Information Services (IIS) Smooth Streaming Manifest (ISM), IIS Smooth Streaming Text (ISMT), Matroska Subtitles (MKS), SubRip (SRT), Timed Text Markup Language (TTML), Web Video Text Tracks (WebVTT or WVTT), Comma-Separated Values (CSV), Extensible Markup Language (XML), Extensible Hypertext Markup Language (XHTML), XML User Interface Language (XUL), JSON, MessagePack, Wireless Markup Language (WML), Yet Another Markup Language (YAML), any other suitable techniques, any predecessors, successors, and variants thereof, and any combinations thereof.

Standards and specifications associated with DRM and encryption may include, but are not limited to, Advanced Encryption Standard (AES) (e.g., AES-128, AES-192, AES-256), Blowfish (BF), Cipher Block Chaining (CBC), Cipher Feedback (CFB), Counter (CTR), Data Encryption Standard (DES), Triple DES (3DES), Electronic Codebook (ECB), FairPlay, Galois Message Authentication Code (GMAC), Galois/Counter Mode (GCM), High-bandwidth Digital Content Protection (HDCP), Output Feedback (OFB), PlayReady, Propagating CBC (PCBC), Trusted Execution Environment (TEE), Verimatrix, Widevine, any other suitable techniques, any predecessors, successors, and variants thereof, and any combinations thereof, such as AES-CBC encryption (CBCS), AES-CTR encryption (CENC).

In some embodiments, a tangible, non-transitory apparatus or article of manufacture including a tangible, non-transitory computer useable or readable medium having control logic (software) stored thereon may also be referred to herein as a computer program product or program storage device. This includes, but is not limited to, computer system 800, main memory 808, secondary memory 810, removable storage unit 818, and removable storage unit 822, as well as tangible articles of manufacture embodying any combination of the foregoing. Such control logic, when executed by one or more data processing devices (such as computer system 800 or processor(s) 804), may cause such data processing devices to operate as described herein.

Based on the teachings contained in this disclosure, it will be apparent to persons skilled in the relevant art(s) how to make and use embodiments of this disclosure using data processing devices, computer systems and/or computer architectures other than that shown in FIG. 8. In particular, embodiments can operate with software, hardware, and/or operating system implementations other than those described herein.

### CONCLUSION

It is to be appreciated that the Detailed Description section, and not any other section, is intended to be used to interpret the claims. Other sections can set forth one or more but not all example embodiments as contemplated by the inventor(s), and thus, are not intended to limit this disclosure or the appended claims in any way.

While this disclosure describes example embodiments for example fields and applications, it should be understood that the disclosure is not limited thereto. Other embodiments and modifications thereto are possible, and are within the scope and spirit of this disclosure. For example, and without limiting the generality of this paragraph, embodiments are not limited to the software, hardware, firmware, and/or entities illustrated in the figures and/or described herein. Further, embodiments (whether or not explicitly described herein) have significant utility to fields and applications beyond the examples described herein.

Embodiments have been described herein with the aid of functional building blocks illustrating the implementation of specified functions and relationships thereof. The boundaries of these functional building blocks have been arbitrarily defined herein for the convenience of the description. Alternate boundaries can be defined as long as the specified functions and relationships (or equivalents thereof) are appropriately performed. Also, alternative embodiments can perform functional blocks, steps, operations, methods, etc. using orderings different than those described herein.

References herein to “one embodiment,” “an embodiment,” “an example embodiment,” or similar phrases, indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it would be within the knowledge of persons skilled in the relevant art(s) to incorporate such feature, structure, or characteristic into other embodiments whether or not explicitly mentioned or described herein. Additionally, some embodiments can be described using the expression “coupled” and “connected” along with their derivatives. These terms are not necessarily intended as synonyms for each other. For example, some embodiments can be described using the terms “connected” and/or “coupled” to indicate that two or more elements are in direct physical or electrical contact with each other. The term “coupled,” however, can also mean that two or more elements are not in direct contact with each other, but yet still co-operate or interact with each other.

The breadth and scope of this disclosure should not be limited by any of the above-described example embodiments, but should be defined only in accordance with the following claims and their equivalents.

What is claimed is:

1. An apparatus, comprising:
at least one processor coupled to an electrical matrix and configured to:
detect, based on an electrical matrix scanning technique, an actuated electrical switch corresponding to a remote control action for a media device, wherein the actuated electrical switch has been actuated in response to a button of a remote control device being pressed by a user, and wherein the actuated electrical switch comprises a first actuated electrode coupled to a first actuated electrical line of the electrical matrix, a second actuated electrode coupled to a second actuated electrical line of the electrical matrix, and a third actuated electrode coupled to a third actuated electrical line of the electrical matrix; and
trigger an execution of the remote control action.

2. The apparatus of claim 1, wherein:
the first actuated electrode comprises an actuated column electrode;
the first actuated electrical line comprises an actuated column electrical line;
the second actuated electrode comprises an actuated row electrode; and
the second actuated electrical line comprises an actuated row electrical line.

3. The apparatus of claim 2, wherein:
the third actuated electrode comprises an actuated page electrode; and
the third actuated electrical line comprises an actuated page electrical line.

4. The apparatus of claim 2, wherein:
the actuated row electrode is a first actuated row electrode;
the actuated row electrical lines is a first actuated row electrical line;
the second actuated electrode comprises a second actuated row electrode; and
the second actuated electrical line comprises a second actuated row electrical line.

5. The apparatus of claim 3, wherein the actuated electrical switch is configured to simulate two buttons of the remote control device being simultaneously pressed by the user.

6. The apparatus of claim 1, wherein to detect the actuated electrical switch, the at least one processor is configured to:
sequentially apply an electrical voltage to each electrical line of a first plurality of electrical lines of the electrical matrix to detect the first actuated electrical line corresponding to the first actuated electrode;
scan each electrical line of a second plurality of electrical lines to detect the second actuated electrical line corresponding to the second actuated electrode;
scan each electrical line of a third plurality of electrical lines to detect the third actuated electrical line corresponding to the third actuated electrode; and
detect the actuated electrical switch based on the first actuated electrical line, the second actuated electrical line, and the third actuated electrical line.

7. The apparatus of claim 1, wherein the electrical matrix is formed on a printed circuit board.

8. A remote control device, comprising:
at least one processor coupled to an electrical matrix and configured to:
detect, based on an electrical matrix scanning technique, an actuated electrical switch corresponding to a remote control action for a media device, wherein the actuated electrical switch has been actuated in response to a button of the remote control device being pressed by a user, and wherein the actuated electrical switch comprises a first actuated electrode coupled to a first actuated electrical line of the electrical matrix, a second actuated electrode coupled to a second actuated electrical line of the electrical matrix, and a third actuated electrode coupled to a third actuated electrical line of the electrical matrix; and
trigger an execution of the remote control action.

9. The remote control device of claim 8, wherein:
the first actuated electrode comprises an actuated column electrode;
the first actuated electrical line comprises an actuated column electrical line;
the second actuated electrode comprises an actuated row electrode; and
the second actuated electrical line comprises an actuated row electrical line.

10. The remote control device of claim 9, wherein:
the third actuated electrode comprises an actuated page electrode; and
the third actuated electrical line comprises an actuated page electrical line.

11. The remote control device of claim 9, wherein:
the actuated row electrode is a first actuated row electrode;
the actuated row electrical lines is a first actuated row electrical line;
the second actuated electrode comprises a second actuated row electrode; and
the second actuated electrical line comprises a second actuated row electrical line.

12. The remote control device of claim 11, wherein the actuated electrical switch is configured to simulate two buttons of the remote control device being simultaneously pressed by the user.

13. The remote control device of claim 8, wherein to detect the actuated electrical switch, the at least one processor is configured to:
sequentially apply an electrical voltage to each electrical line of a first plurality of electrical lines of the electrical matrix to detect the first actuated electrical line corresponding to the first actuated electrode;
scan each electrical line of a second plurality of electrical lines to detect the second actuated electrical line corresponding to the second actuated electrode;
scan each electrical line of a third plurality of electrical lines to detect the third actuated electrical line corresponding to the third actuated electrode; and
detect the actuated electrical switch based on the first actuated electrical line, the second actuated electrical line, and the third actuated electrical line.

14. The remote control device of claim 8, wherein the electrical matrix is formed on a printed circuit board.

15. A computer-implemented method for remotely controlling a media device, comprising:
detecting, by at least one processor and using an electrical matrix scanning technique, an actuated electrical switch corresponding to a remote control action for a media device, wherein the actuated electrical switch has been actuated in response to a button of a remote control device being pressed by a user, and wherein the actuated electrical switch comprises a first actuated electrode coupled to a first actuated electrical line of an electrical matrix, a second actuated electrode coupled to a second actuated electrical line of the electrical matrix, and a third actuated electrode coupled to a third actuated electrical line of the electrical matrix; and
triggering, by the at least one processor and in response to detecting the actuated electrical switch, an execution of the remote control action.

16. The computer-implemented method of claim 15, wherein:
the first actuated electrode comprises an actuated column electrode;
the first actuated electrical line comprises an actuated column electrical line;
the second actuated electrode comprises an actuated row electrode; and
the second actuated electrical line comprises an actuated row electrical line.

17. The computer-implemented method of claim 16, wherein:
the third actuated electrode comprises an actuated page electrode; and
the third actuated electrical line comprises an actuated page electrical line.

18. The computer-implemented method of claim 16, wherein:
the actuated row electrode is a first actuated row electrode;
the actuated row electrical lines is a first actuated row electrical line;
the second actuated electrode comprises a second actuated row electrode; and
the second actuated electrical line comprises a second actuated row electrical line.

19. The computer-implemented method of claim 18, wherein the actuated electrical switch simulates two buttons of the remote control device being simultaneously pressed by the user.

20. The computer-implemented method of claim 15, wherein the detecting the actuated electrical switch comprises:
sequentially applying, by the at least one processor, an electrical voltage to each electrical line of a first plurality of electrical lines of the electrical matrix to detect the first actuated electrical line corresponding to the first actuated electrode;
scanning, by the at least one processor, each electrical line of a second plurality of electrical lines to detect the second actuated electrical line corresponding to the second actuated electrode;
scanning, by the at least one processor, each electrical line of a third plurality of electrical lines to detect the third actuated electrical line corresponding to the third actuated electrode; and
detecting, by the at least one processor, the actuated electrical switch based on the first actuated electrical line, the second actuated electrical line, and the third actuated electrical line.
